(19) United States
(12) Patent Application Publication
(10) Pub. No.: US 2013/0052902 A1
(43) Pub. Date: Feb. 28, 2013

(54) METHOD OF REPAIRING A DISPLAY PANEL AND APPARATUS FOR PERFORMING THE SAME

(71) Applicants: Woo-Sik Jun, Yongin-si (KR); Hyun-Been Hwang, Yongin-si (KR)

(72) Inventors: Woo-Sik Jun, Yongin-si (KR); Hyun-Been Hwang, Yongin-si (KR)

(73) Assignee: SAMSUNG MOBILE DISPLAY CO., LTD., Yongin-city (JP)

(21) Appl. No.: 13/292,995

(22) Filed: Nov. 9, 2011

(30) Foreign Application Priority Data
Aug. 22, 2011 (KR) 10-2011-0083304

(51) Int. Cl. H01J 9/50; H01J 9/20

(52) U.S. Cl. 445/24; 445/61

(57) ABSTRACT

In a method of repairing a display panel, only a defective portion of the display panel is lighted. Heat generated from the lighted defective portion is detected to obtain a position of a defect in the defective portion. A laser is irradiated onto the defective portion to repair the defective portion. The heat generated from the lighted shorted portion is detected using infrared light to obtain an accurate position of the defect in the shorted portion. Thus, an invisible minute defect such as a tiny short can be accurately repaired, so that a yield of the display panel is improved.

### CROSS-REFERENCE TO RELATED APPLICATIONS

This application claims priority under 35 U.S.C. §119 to Korean patent Application No. 10-2011-0083304, filed on Aug. 22, 2011, the disclosure of which is hereby incorporated by reference herein in its entirety.

### BACKGROUND

1. Field

Embodiments of the invention relate to a method of repairing a display panel of an organic light emitting display device, and an apparatus for performing the method.

2. Description of the Related Technology

An organic light emitting display (OLED) device may display desired information such as images, letters and/or characters using light generated by combining holes provided from an anode with electrons provided from a cathode in an organic layer thereof. From among various display devices, such as, for example, liquid crystal display devices, plasma display panels, field emission display devices, etc., the OLED device has been widely employed in various electronic and electric apparatuses such as televisions, mobile communication apparatuses, monitors, MP3 players, portable display apparatuses and the like, because the OLED device may ensure a relatively large view angle, a rapid response speed, a small thickness, and a low power consumption. Accordingly, the OLED device is among one of the most promising next-generation display devices.

Generally a defect may be generated in the OLED device while manufacturing the OLED device. Such defect may decrease a capacity, a degree and/or performance of the OLED device. Thus, it may be required to detect the defect of the OLED device by a lighting test. The defect of the OLED device may generally include conductive particles in an organic light emitting layer. The conductive particles may electrically connect an anode to a cathode to generate an electrical short between the anode and the cathode. A pixel of the OLED device having the shorted portion may act as a dark spot. Therefore, in order to increase a yield of the OLED device, it may be required to repair the defect of the OLED device.

However, invisible minute particles may not be accurately detected using a conventional repairing method. Thus, a ratio of defects removed by the conventional repairing method may be very low. As a result, the yield of manufacturing the OLED device may be reduced.

### SUMMARY OF CERTAIN INVENTIVE ASPECTS

Embodiments provide a method of repairing a display panel that is capable of accurately detecting an invisible minute defect.

Embodiments also provide an apparatus for performing the method of repairing a display panel.

According to one aspect, there is provided a method of repairing a display panel. In the method of repairing a display panel, only a defective portion of the display panel can be lighted. Heat generated from the lighted defective portion can be detected to obtain a position of a defect in the defective portion. A laser can be irradiated onto the defective portion to repair the defective portion of the display panel.

In some embodiments, the display panel can be arranged in a repair chamber where visible light may not exist. The heat generated from the lighted defective portion can be detected using an infrared light.

In some embodiments, a reverse bias voltage can be applied to the display panel to thereby light only the defective portion of the display panel.

In some embodiments, the defective portion of the display panel can be magnified, and the magnified defective portion of the display panel can be displayed to identify the position of the defect.

According to another aspect, there is provided a method of repairing a display panel. In the method of repairing a display panel, the display panel can be arranged in a repair chamber where visible light may not exist. A reverse bias voltage can be applied to the display panel to light only a shorted portion of the display panel. Heat generated from the lighted shorted portion can be detected using an infrared light to obtain a position of a defect in the shorted portion. A laser can be irradiated onto the shorted portion to repair the shorted portion.

In some embodiments, the short portion of the display panel can be magnified, and the magnified shorted portion can be displayed.

According to still another aspect, there is provided an apparatus for repairing a display panel. The apparatus can include a lighting unit, a heat-detecting unit and a laser-irradiating unit. The lighting unit can light only a defective portion of the display panel. The heat-detecting unit can detect heat generated from the lighted defective portion to obtain a position of a defect in the defective portion. The laser-irradiating unit can irradiate a laser onto the defective portion to repair the defective portion.

In some embodiments, the apparatus can further include a repair chamber configured to receive the lighting unit, the heat-detecting unit and the laser-irradiating unit. The repair chamber can have an inner space where a visible light may not exist. The heat-detecting unit can include an infrared light-detecting member for detecting the heat generated from the defective portion using an infrared light.

In some embodiments, the lighting unit can include a jig configured to receive the display panel, and a bias-applying member configured to apply a reverse bias voltage to the display panel on the jig.

In some embodiments, the apparatus can further include a display unit configured to display a magnified defective portion of the display panel.

In some embodiments, the apparatus can further include a transferring unit for transferring the heat-detecting unit and the laser-irradiating unit over the defective portion of the display panel.

According to still another aspect, there is provided an apparatus for repairing a display panel. The apparatus can include a repair chamber, a lighting unit, a heat-detecting unit and a laser-irradiating unit. The repair chamber can have an inner space configured to receive the display panel. Visible light may not exist in the inner space of the repair chamber. The lighting unit can be arranged in the repair chamber and be configured to light only a defective portion of the display panel. The heat-detecting unit can be arranged over the lighting unit in the repair chamber and be configured to detect heat generated from the lighted defective portion, thereby obtaining a position of a defect in the defective portion. The laser-irradiating unit can be arranged over the lighting unit in the repair chamber to irradiate a laser onto the defective portion to repair the defective portion.

In some embodiments, the lighting unit can include a jig configured to receive the display panel, and a bias-applying member configured to apply a reverse bias voltage to the display panel on the jig.

In some embodiments, the apparatus can further include a display unit arranged over the lighting unit in the repair chamber and configured to display a magnified defective portion of the display panel.

In some embodiments, the apparatus can further include a transferring unit arranged in the repair chamber to transfer the heat-detecting unit and the laser-irradiating unit over the defective portion of the display panel.

According to some embodiments, the reverse bias voltage can be applied to the display panel to light only the shorted portion or the defective portion. The heat generated from the lighted shorted portion or the defective portion can be detected using the infrared light to obtain an accurate position of the defect in the shorted portion or the defective portion. Thus, an invisible minute defect such as a tiny short can be accurately repaired, so that a yield of the display panel can be improved.

### BRIEF DESCRIPTION OF THE DRAWINGS

Certain embodiments can be understood in more detail from the following description taken in conjunction with the accompanying drawings, in which:

FIG. 1 is a cross-sectional view illustrating an embodiment of an apparatus for repairing a display panel;

FIG. 2 is a flow chart illustrating an embodiment of a method of repairing a display panel using the apparatus illustrated in FIG. 1;

FIG. 3 is a scanning electron microscope (SEM) picture showing a shorted portion of the display panel photographed by the apparatus illustrated in FIG. 1; and

FIG. 4 is an SEM picture showing a repaired shorted portion using the apparatus illustrated in FIG. 1.

### DETAILED DESCRIPTION OF CERTAIN INVENTIVE EMBODIMENTS

Certain embodiments are described more fully hereinafter with reference to the accompanying drawings. The invention may, however, be embodied in many different forms and should not be construed as limited to the embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals generally refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross sectional illustrations that are schematic illustrations of illustratively idealized embodiments (and intermediate structures) of the invention. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

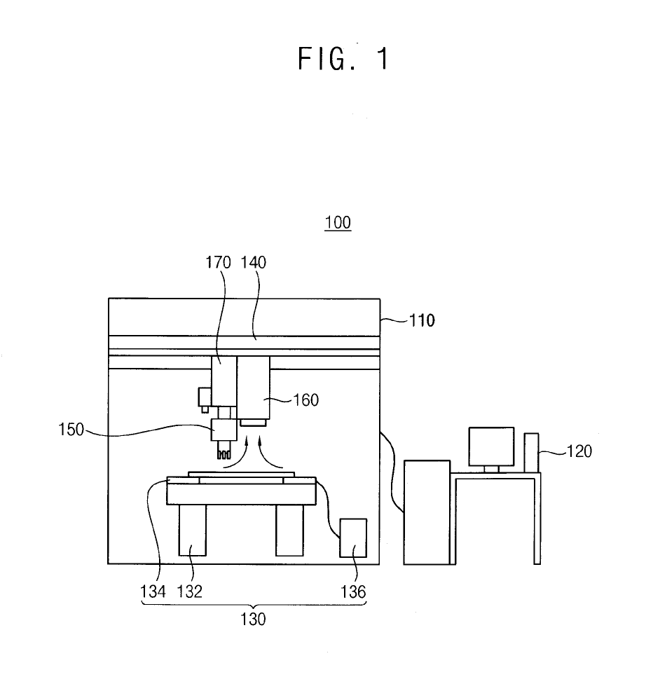

FIG. 1 is a cross-sectional view illustrating an embodiment of an apparatus for repairing a display panel.

Referring to FIG. 1, an embodiment of apparatus 100 for repairing a display panel includes a repair chamber 110, a control unit 120, a lighting unit 130, a transferring unit 140, a display unit 150, a heat-detecting unit 160 and a laser-irradiating unit 170.

In some embodiments, the display panel can be an organic light emitting display (OLED) panel. For example, the display panel can be an active matrix OLED (AMOLED) panel. The AMOLED panel can include an anode, a cathode and an organic light emitting layer disposed between the anode and the cathode. Each of the anode and the cathode can include a transparent material or a reflective material, and the organic light emitting layer can include a material for generating a red color of light, a green color of light and/or a green color of light. The organic light emitting layer can have a single-layered structure or a multi-layered structure. A defect of the AMOLED panel can be mainly generated in the organic light emitting layer. The defect can include conductive particles that electrically connect the anode to the cathode to thereby generate an electrical short between two electrodes (i.e., the anode and the cathode). The conductive particles can have invisible minute sizes.

The repair chamber 110 has an inner space configured to receive the AMOLED panel therein. In some embodiments, visible light may not exist in the inner space of the repair chamber 110. For example, visible light may not pass into the inner space of the repair chamber 110. Thus, the repair chamber 110 can include a material having a color and/or a property for blocking the visible light.

The control unit 120 controls operations of the lighting unit 130, the transferring unit 140, the display unit 150, the heat-detecting unit 160 and the laser-irradiating unit 170. A position of an abnormal pixel, which can be detected in a lighting test for the AMOLED panel, can be inputted into the control unit 120. The abnormal pixel can have a defect caused by particles.

The lighting unit 130 can be arranged on a bottom face of the repair chamber 110. In some embodiments, the lighting unit 130 can include a stage 132, a jig 134 and a bias-applying member 136.

The stage 132 can be positioned on the bottom face of the repair chamber 110. The jig 134 can be arranged on an upper face of the stage 132. The AMOLED panel can be placed on an upper face of the jig 134. The bias-applying member 136 can be electrically connected to the jig 134. The bias-applying member 136 can turn on only a shorted pixel (i.e., a pixel having a defect) of the AMOLED panel. A pixel having a defect such as a short and a portion of the pixel having a defect such as a short are referred to herein as a shorted pixel or a defective pixel, and a shorted portion of a pixel or a defective portion of a pixel, respectively. Further, a pixel including a defect and a portion of the pixel including a defect are respectively referred to herein as an abnormal pixel and an abnormal portion of a pixel.

In some embodiments, when a forward bias voltage is applied to the AMOLED panel, a shorted abnormal pixel (i.e., a pixel having a defect such as a short) as well as a normal pixel is be lighted. In contrast, when a reverse bias voltage is applied to the AMOLED panel, only the shorted abnormal pixel is lighted whereas the normal pixel is not be lighted. Thus, the bias-applying member 136 can apply the reverse bias voltage to the AMOLED panel through the jig 134 to light the shorted pixel only. Heat may be generated from the lighted shorted pixel.

The transferring unit 140 can be positioned at an upper region of the inner space of the repair chamber 110. The transferring unit 140 can transfer the display unit 150, the heat-detecting unit 160 and the laser-irradiating unit 170 in an X direction and a Y direction. In some embodiments, the transferring unit 140 can transfer the display unit 150, the heat-detecting unit 160 and the laser-irradiating unit 170 toward the upper region of the inner space of the repair chamber 110 over the abnormal pixel by a control signal provided from the control unit 120.

The display unit 150 can be installed on the transferring unit 140. The display unit 150 can be arranged over the jig 134. The display unit 150 magnifies the shorted abnormal pixel and displays the shorted abnormal pixel on a monitor of the control unit 120. In some embodiments, the display unit 150 can include a microscope.

The heat-detecting unit 160 can be installed on the transferring unit 140. The heat-detecting unit 160 can be arranged over the jig 134. The heat-detecting unit 160 detects the heat generated from the lighted abnormal pixel to obtain an accurate position of a shorted portion in the lighted abnormal pixel.

In some embodiments, the heat-detecting unit 160 can include an infrared detecting member or a near infrared detecting member, which detects the heat using infrared light. The infrared detecting member 160 can be very sensitive to the visible light. When visible light exists in the inner space of the repair chamber 110, the infrared detecting member 160 may not accurately detect the heat generated from the lighted abnormal pixel. Thus, in order to detect a precise position of the heat generated from the lighted abnormal pixel using the infrared light, it may be required to maintain the inner space of the repair chamber 110 being free of visible light.

The laser-irradiating unit 170 can irradiate a laser onto the position where the heat is generated, which can substantially correspond to the shorted portion of the abnormal pixel and can be detected by the heat-detecting unit 160 to repair the defect of the display panel. In some embodiments, when the defect includes the short, the laser-irradiating unit 170 can remove a portion of the cathode over the conductive particles to isolate the cathode from the anode. For example, the laser can include an Nd:TAG laser, an Nd:YLF laser, an Nd:YV04 laser, a Ti:Sapphire laser, and the like.

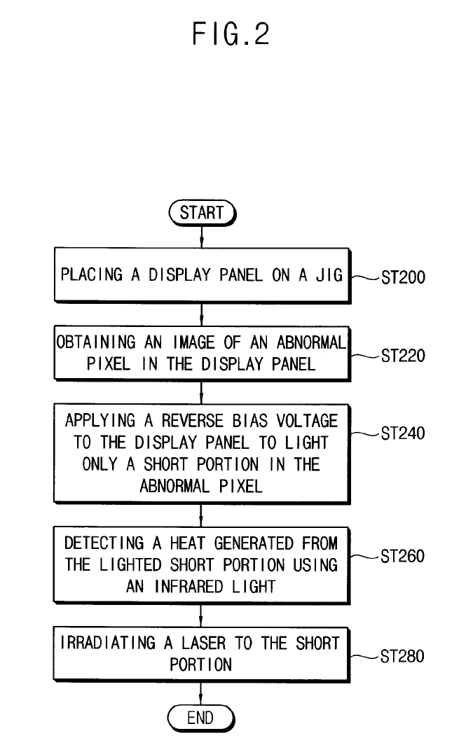

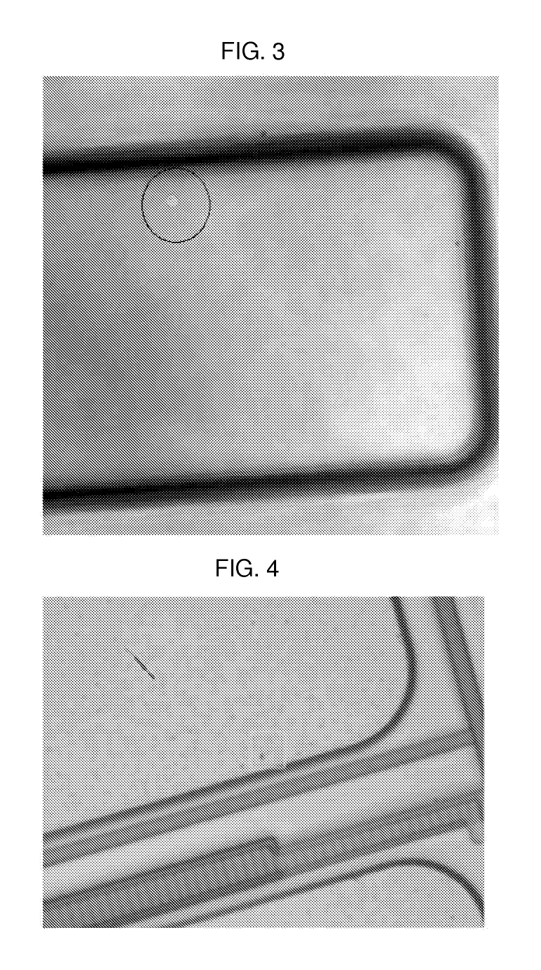

FIG. 2 is a flow chart illustrating an embodiment of a method of repairing a display panel using the apparatus illustrated in FIG. 1. FIG. 3 is a scanning electron microscope (SEM) picture showing a shorted portion of the display panel photographed by the apparatus illustrated in FIG. 1. FIG. 4 is an SEM picture showing a repaired shorted portion using the apparatus illustrated in FIG. 1.

Referring to FIGS. 1 and 2, in step ST200, the AMOLED panel is loaded into the repair chamber 110. In some embodiments, the repair chamber 110 has the inner space free of visible light. The AMOLED panel can be placed on the jig 134.

In step ST220, the transferring unit 140 transfers the display unit 150 to a position over the abnormal pixel of the AMOLED panel having the shorted portion. In some embodiments, the position of the abnormal pixel, which is detected in a lighting test for the AMOLED panel, is input into the control unit 120. The transferring unit 140 transfers the display unit 150 to the position over the abnormal pixel of the AMOLED panel by a control signal transmitted from the control unit 120.

The display unit 150 magnifies the abnormal pixel. For example, the display unit 150 magnifies a size or a dimension of the abnormal pixel including the shorted portion. The display unit 150 then displays an image of the magnified abnormal pixel on the monitor of the control unit 120. Hence, a worker can watch the magnified image to determine whether the magnified pixel is normal or not. That is, the worker can identify the abnormal pixel through the magnified image.

In step ST240, the bias-applying member 136 applies a reverse bias voltage to the AMOLED panel to light the shorted portion of the abnormal pixel. When the reverse bias voltage is applied to the AMOLED panel, only the shorted portion of the abnormal pixel is lighted. In contrast, normal portions of the abnormal pixel (i.e., portions of the abnormal pixel having no defects such as shorts) and the normal pixel are not lighted. Thus, heat is generated from the lighted shorted portion of the abnormal pixel.

In step ST260, the heat-detecting unit 160 detects the heat generated from the lighted shorted portion of the abnormal pixel using the infrared light. In some embodiments, visible light does not exist or permeate in the inner space of the repair chamber 110. Therefore, as illustrated in FIG. 3, the heat-detecting unit 160 accurately detects a position of the heat using the infrared light. The position of the heat is input into the control unit 120.

In step ST280, a worker may identify the position of the heat input into the control unit 120 to determine a sort of the laser, an area where the laser is irradiated, a depth to which the laser is incident, and the like.

The laser-irradiating unit 170 irradiates the determined laser to the detected shorted portion of the abnormal pixel to repair the detected shorted portion. In some embodiments, the laser is irradiated onto the cathode to remove a portion of the cathode over the conductive particles. Thus, the cathode and the anode, which are electrically connected to each other via the conductive particles, can be isolated from each other.

After the shorted portion of the abnormal pixel is repaired, the forward bias voltage is applied to the AMOLED panel to perform the lighting test of the AMOLED panel. As illustrated in FIG. 4, it can be noted that the repaired portion is normally lighted.

According to some embodiments, a reverse bias voltage is applied to a display panel to light only a shorted portion (i.e., a defective portion) of a pixel of the display panel or a shorted pixel (i.e., a defective pixel) of the display device. Heat generated from the lighted shorted portion of the pixel or the lighted defective pixel is detected using infrared light to obtain an accurate position of the shorted portion of the pixel or the defective pixel of the display panel. Thus, a defect such as an invisible minute short can be accurately repaired, so that a yield of the display panel can be improved.

The foregoing is illustrative of certain embodiments, and is not to be construed as limiting thereof. Although certain embodiments have been described, those skilled in the art will readily appreciate that many modifications are possible in the embodiments without materially departing from the novel teachings and advantages. Accordingly, all such modifications are intended to be included within the scope of embodiments as defined in the claims. In the claims, means-plus-function clauses are intended to cover the structures described herein as performing the recited function and not only structural equivalents but also equivalent structures. Therefore, it is to be understood that the foregoing is illustrative of certain embodiments and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A method of repairing a display panel, the method comprising:
lighting only a defective portion of the display panel;
detecting heat generated from the lighted defective portion to obtain a position of a defect in the defective portion; and
irradiating a laser onto the defective portion to repair the defective portion.

2. The method of claim 1, further comprising arranging the display panel in a space without visible light, wherein detecting the heat generated from the lighted defective portion comprises detecting the heat using an infrared light.

3. The method of claim 1, wherein lighting only the defective portion comprises applying a reverse bias voltage to the display panel.

4. The method of claim 1, further comprising displaying a magnified defective portion.

5. The method of claim 1, wherein the display panel comprises an organic lighting emitting display (OLED) panel, and the defect comprises a short in an organic lighting emitting layer between an anode and a cathode of the OLED panel.

6. A method of repairing a display panel, the method comprising:
arranging the display panel in a space without visible light,
applying a reverse bias voltage to the display panel to light only a shorted portion of the display panel;
detecting heat generated from the lighted shorted portion using an infrared light to obtain a position of a defect in the shorted portion; and
irradiating a laser onto the shorted portion to repair the shorted portion.

7. The method of claim 6, further comprising displaying a magnified shorted portion.

8. An apparatus for repairing a display panel, the apparatus comprising:
a lighting unit for lighting only a defective portion of the display panel;
a heat-detecting unit for detecting heat generated from the lighted defective portion to obtain a position of a defect in the defective portion; and
a laser-irradiating unit for irradiating a laser onto the defective portion to repair the defective portion.

9. The apparatus of claim 8, further comprising a repair chamber configured to receive the lighting unit, the heat-detecting unit and the laser-irradiating unit, wherein the repair chamber has an inner space without visible light, and the heat-detecting unit comprises an infrared detecting member for detecting the heat using an infrared light.

10. The apparatus of claim 8, wherein the lighting unit comprises:
a jig on which the display panel is placed; and
a bias-applying member configured to apply a reverse bias voltage to the display panel on the jig.

11. The apparatus of claim 8, further comprising a display unit for displaying a magnified defective portion of the display panel.

12. The apparatus of claim 8, further comprising a transferring unit configured to transfer the heat-detecting unit and the laser-irradiating unit over the defective portion of the display panel.

13. An apparatus for repairing an OLED panel, the apparatus comprising:
a repair chamber configured to receive the OLED panel, the repair chamber having an inner space being free of visible light;
a lighting unit arranged in the repair chamber, the lighting unit configured to light only a shorted portion of the OLED panel;
a heat-detecting unit arranged over the lighting unit in the repair chamber, the heat-detecting unit configured to detect heat generated from the lighted shorted portion using an infrared light and to obtain a position of a defect in the shorted portion; and
a laser-irradiating unit arranged over the lighting unit in the repair chamber, the laser-irradiating unit configured to repair the shorted portion by irradiating a laser onto the shorted portion.

14. The apparatus of claim 13, wherein the lighting unit comprises:
a jig on which the OLED panel is placed; and
a bias-applying member configured to apply a reverse bias voltage to the OLED panel on the jig.

15. The apparatus of claim 13, further comprising a display unit arranged over the lighting unit in the repair chamber, the display unit configured to display a magnified shorted portion of the display panel.

16. The apparatus of claim 13, further comprising a transferring unit arranged in the repair chamber to transfer the heat-detecting unit and the laser-irradiating unit over the shorted portion of the display panel.
